(19) United States
(12) Patent Application Publication
(10) Pub. No.: US 2017/0047552 A1
(43) Pub. Date: Feb. 16, 2017

(54) ORGANIC LIGHT-EMITTING COMPONENT

(71) Applicant: OSRAM OLED GMBH, Regensburg (DE)

(72) Inventor: Arne Fleißner, Regensburg (DE)

(21) Appl. No.: 15/305,728

(22) PCT Filed: Apr. 28, 2015
(86) PCT No.: PCT/EP2015/059188

§ 371 Date: Oct. 21, 2016

(30) Foreign Application Priority Data
May 9, 2014 (DE) 10 2014 106 549.2

(51) Int. Cl. H01L 51/52; H01L 51/50

(52) U.S. Cl. CPC H01L 51/5271; H01L 51/5268; H01L 51/5234; H01L 51/5088

(57) ABSTRACT

An organic light-emitting component includes: a translucent first electrode and a second electrode, and an organic functional layer stack having at least one organic light-emitting layer between the first and second electrodes, wherein the second electrode is diffusely reflective; a translucent first electrode and a second electrode, and an organic functional layer stack having at least one organic light-emitting layer between the first and second electrodes, wherein the second electrode is diffusely reflective, and the second electrode layer includes a multiplicity of crystals with boundary surfaces for diffuse reflection; and a translucent first electrode and a second electrode, and an organic functional layer stack having at least one organic light-emitting layer between the first and second electrodes, wherein the second electrode is diffusely reflective, and the second electrode layer includes barium sulfate.

### TECHNICAL FIELD

This disclosure relates to an organic light-emitting component.

### BACKGROUND

In organic light-emitting diodes (OLEDs), owing to the total reflection between the organic layers having a relatively high refractive index and a substrate having a lower refractive index, a waveguide is produced, whereby a large proportion of light generated in the organic layer stack remains in the OLED. Therefore, for highly efficient OLEDs, measures for internal outcoupling of light are required to ensure that as much of the light generated in the OLED as possible can leave the OLED.

It is known to achieve such an internal outcoupling from an OLED by virtue of the fact that a translucent internal outcoupling structure is integrated between the substrate and the electrode arranged thereon. This structure is, e.g., so-called “low index grids” or even layers consisting of highly refractive, transparent materials containing scattering centers, e.g., high-index polymers or glasses having SiO₂ or TiO₂microparticles.

However, the known arrangement of the internal outcoupling layer between the substrate and the lower electrode may be disadvantageous. For example, polymer layers between the substrate and electrode can be a path of penetration for water and oxygen which impedes an effective encapsulation of the OLED. Furthermore, it is possible that the internal outcoupling layer has a rough surface, whereby during production of the organic layer stack on the rough surface, defects in the OLED can occur or, to avoid such defects, planarization of the outcoupling structure is required. The likelihood of errors occurring and process complexity and manufacturing costs are hereby increased. Furthermore, it is possible that the presence of an internal outcoupling structure on the substrate limits the processing options when manufacturing the OLED, e.g., if the outcoupling layer is incompatible with a structuring, e.g., a photolithographic structuring, of the lower electrode.

For an OLED to be as efficient as possible, in the prior art (in particular also in conjunction with internal outcoupling structures) electrodes that are as highly reflective as possible are used on the side of the organic layers opposite the outcoupling structure. For that purpose, typically sufficiently thick metal electrodes having high reflectivity are used, in particular consisting of cost-intensive silver, wherein the reflectivity of such reflective metal electrodes is oriented in the same direction and is specular in nature.

Furthermore, specific organic semiconductor materials are known such as, e.g., the material NET-61 from Novaled and crystallizes upon being thermally vapor deposited on underlying organic semiconductor layers. Owing to the thereby produced morphology of the NET-61, the boundary surface between the organic layer stack and a metallic electrode vapor deposited thereon is not flat, but is wave-shaped and can reduce a waveguide in the organic layer stack as described, for example, in Pavicic et al., Proceedings of International Display Week (2011) 459. However, a disadvantage thereof is the commitment to a specific organic material that extremely limits the design freedom in relation to the organic layers.

It could therefore be helpful to provide a more efficient organic light-emitting component.

### SUMMARY

I provide an organic light-emitting component including a translucent first electrode and a second electrode, and an organic functional layer stack having at least one organic light-emitting layer between the first and second electrodes, wherein the second electrode is diffusely reflective.

I also provide an organic light-emitting component including a translucent first electrode and a second electrode, and an organic functional layer stack having at least one organic light-emitting layer between the first and second electrodes, wherein the second electrode is diffusely reflective, and the second electrode layer includes a multiplicity of crystals with boundary surfaces for diffuse reflection.

I further provide an organic light-emitting component including a translucent first electrode and a second electrode, and an organic function layer stack having at least one organic light-emitting layer between the first and second electrodes, wherein the second electrode is diffusely reflective, and the second electrode layer includes barium sulfate.

### BRIEF DESCRIPTION OF THE DRAWINGS

FIG. 1 shows a schematic illustration of an organic light-emitting component according to an example.

FIG. 2 shows a schematic illustration of an organic light-emitting component according to a further example.

### DETAILED DESCRIPTION

My organic light-emitting component may comprise at least one translucent first electrode and one second electrode, between which an organic functional layer stack is arranged. The organic functional layer stack comprises at least one organic light-emitting layer in the form of an organic electroluminescent layer configured to generate light during operation of the organic light-emitting component. In particular, the organic light-emitting component can be formed as an organic light-emitting diode (OLED).

“Translucent” means a layer permeable to visible light. The translucent layer can be transparent, i.e., clear-diaphanous, or can be at least partially light-scattering and/or partially light-absorbing so that the translucent layer can also be, for example, diffuse- or milky-diaphanous. Particularly preferably, a layer referred to herein as translucent has as low an absorption of light as possible.

The organic functional layer stack can comprise layers with organic polymers, organic oligomers, organic monomers, organic small, non-polymeric molecules (“small molecules”) or combinations thereof. Suitable materials for the organic light-emitting layer are materials comprising a radiation emission by reason of fluorescence or phosphorescence, e.g., polyfluorene, polythiophene or polyphenylene or derivatives, compounds, mixtures or copolymers thereof. The organic functional layer stack can also comprise a plurality of organic light-emitting layers are arranged between the electrodes. The organic functional layer stack can further comprise charge carrier injection layers, charge carrier transport layers and/or charge carrier blocking layers.

The organic light-emitting component may comprise a substrate on which the electrodes, i.e., the translucent first electrode and the second electrode, and the organic functional layer stack are applied. The substrate can comprise, e.g., one or more materials in the form of a layer, a plate, a film or a laminate selected from glass, quartz, synthetic material, metal, silicon wafer. Particularly preferably, the substrate comprises or consists of glass and/or synthetic material, e.g., in the form of a glass layer, glass film, glass plate, synthetic material layer, synthetic material film, synthetic material plate or a glass-synthetic material laminate. In addition, the substrate, e.g., in synthetic material being the substrate material, can comprise one or more barrier layers that seal the synthetic material.

With regard to the basic structure of an organic light-emitting component, e.g., with regard to the structure, the layer composition and the materials of the organic functional layer stack, reference is made to WO 2010/066245 A1, the subject matter of which is hereby expressly incorporated by reference, in particular in relation to the structure, the layer composition and the materials of the organic functional layer stack.

The second electrode may be diffusely reflective. This means that the second electrode is as highly reflective as possible, i.e., has as high a reflection coefficient as possible, but has a diffuse reflection instead of a specular reflection. In particular, the second electrode is as highly reflective as possible in conjunction with a diffuse scattering. In contrast to a reflective electrode, the light reflected at the second electrode described herein is not reflected in a targeted manner, but rather, as is necessary for an internal outcoupling structure which is as efficient as possible, is distributed, if possible, in all spatial directions so that a waveguide is prevented, if possible, in the organic functional layer stack and/or further layers of the organic light-emitting component. It is thus possible that the second electrode of the organic light-emitting component described herein is already used as an internal outcoupling structure.

The second electrode may comprise at least two electrode layers. In particular, the second electrode can comprise a translucent electrically conductive first electrode layer. This can ensure the electrical functionality of the second electrode. Furthermore, the second electrode can comprise a diffusely reflective second electrode layer arranged on a side of the first electrode layer facing away from the organic functional layer stack. The second electrode layer is formed in particular as a diffuser layer with high reflectivity and ensures the desired optical property of the diffuse reflection.

Compared to OLEDs having conventional electrodes, i.e., in particular a specularly reflective electrode on one side of the organic layers and a translucent electrode on the other side of the organic layers, and without an internal outcoupling structure, the use of the second electrode described herein having the two electrode layers permits an increased efficiency during operation of the organic light-emitting component because a substantially larger proportion of the light generated in the organic functional layer stack can be coupled out.

Furthermore, in the organic light-emitting component described herein, problems such as those that can be produced by the typical arrangement of an internal translucent outcoupling layer between the substrate and the adjacent electrode can be avoided. For instance, the organic light-emitting component described herein can initially be formed, as is conventional, on a typical substrate, e.g., in an arrangement of the second electrode on a side of the organic functional layer stack facing away from the substrate. The risk of defects present when an organic functional layer stack is applied directly on an internal translucent outcoupling layer is thereby obviated. Furthermore, there is no need to provide an additional planarization layer often used in the prior art. Furthermore, typical available substrates such as. e.g., glass coated with indium tin oxide can be used and the typical process steps can be used such as, e.g., photolithography without there being the risk of damage to an internal translucent outcoupling layer located on the substrate. In contrast to the use of specific organic semiconductor materials which, when applied, form a rough surface structure and signify a limitation in the selection of the organic materials, in the organic light-emitting component described herein there is no limitation in the selection of the organic materials and design of the organic functional layer stack.

In particular, the organic light-emitting component can be free of a further translucent scattering layer that would form a known internal translucent outcoupling layer. This means in particular that the organic light-emitting component may be free of a translucent scattering layer on a side of the organic functional layer stack facing away from the second electrode. A “translucent scattering layer” means in particular a translucent layer having a scattering effect additionally introduced into the layer stack as is known and which forms an internal outcoupling structure but not, e.g., the first electrode, the substrate or even an encapsulation arrangement.

The transparent first electrode layer of the second electrode arranged between the second electrode layer and the organic functional layer stack and ensures the electrical contacting of the organic functional layer stack on one side, may comprise at least one or more layers having a translucent electrically conductive material.

For example, the translucent first electrode layer can comprise or consist of a transparent conductive oxide. Transparent conductive oxides (TCOs) are transparent conductive materials, generally metal oxides such as, for example, zinc oxide, tin oxide, cadmium oxide, titanium oxide, indium oxide, indium tin oxide (ITO) or aluminum zinc oxide (AZO). In addition to binary metal-oxygen compounds such as, e.g., ZnO, SnO₂ or In₂O₃, ternary metal-oxygen compounds such as, e.g., Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs.

Furthermore, the TCOs do not necessarily correspond to a stoichiometric composition and may also be p- or n-doped. Furthermore, the translucent first electrode layer can comprise a metal layer having a metal or an alloy, e.g., with one or more of the following materials: Ag, Pt, Au, Mg, Ag:Mg. In this case, the metal layer has a thickness thin enough to be at least partially permeable for light, e.g., a thickness of less than or equal to 50 nm or less than or equal to 20 nm. Furthermore, the translucent first electrode layer can comprise or consist of silver nanowires (SNW). Therefore, the first electrode layer can comprise in particular at least one layer selected from a layer having a transparent conductive oxide, a translucent metal layer and a layer with silver nanowires. Furthermore, the translucent first electrode layer can also comprise or consist of a metal grid in combination with a highly conductive hole injection layer or a conductive polymer. The translucent first electrode layer can also comprise or consist of at least one or more TCO layers, at least one or more translucent metal layers and/or at least one or more layers with silver nanowires.

In particular, the translucent first electrode layer preferably has as low an absorption as possible and thus as high a permeability for light as possible to achieve an efficiency of the organic light-emitting component which is as high as possible. The translucent first electrode layer can be applied, depending upon the selected material, using different methods, e.g., in a TCO or metal by sputtering or thermal evaporation or in silver nanowires, e.g., by a solvent-based process.

The first electrode can comprise or consist of one or more of the materials previously described for the first electrode layer of the second electrode. The first electrode and the first electrode layer of the second electrode may be formed identically or even differently.

The second electrode layer, arranged above the translucent first electrode layer as seen from the organic functional layer stack, comprises in particular a material having diffuse reflection or with a diffuse scattering in combination with a high reflection coefficient. For example, the second electrode layer can comprise a material as used for coatings in integrating spheres. The second electrode layer can have in particular a reflection coefficient of greater than or equal to 95% or greater than or equal to 98%. Optical properties described here and hereinafter such as translucency or a reflection coefficient, refer typically to visible light, in particular that visible light generated by the organic functional layer stack during operation.

The electrode layer may comprise at least one material selected from magnesium oxide (MgO) and barium sulfate (BaSO₄). In some Examples, TEFLON may also be suitable. Layers consisting of these materials can have very high reflection coefficients, e.g., in magnesium oxide of greater than or equal to 95% and in barium sulfate of greater than or equal to 98%, and thereby have very good diffuser properties. In particular, the second electrode layer can be diffusely scattering with a substantially Lambertian radiation characteristic. The diffusely reflective second electrode layer can be applied, depending upon the material, using different methods, e.g., sputtering or thermal evaporation, in particular in magnesium oxide, or by spray coating, e.g., in barium sulfate.

In particular, it can be possible that reflectivity of the second electrode layer preferably formed as a through-going cohesive layer is not based on a boundary surface scattering at a surface of the second electrode layer, i.e., in particular the surface of the second electrode layer facing the first electrode layer, but rather on a volume scattering within the second electrode layer formed as a diffuser layer. For this purpose, the second electrode layer can comprise a multiplicity of particles and/or crystals with boundary surfaces for diffuse reflection. In this respect, the second electrode layer can be formed, for example, of a material containing particles or a material formed by particles. In other words, the material of the second electrode layer does not have to have any absorption, or only very little absorption and, at the same time, inner boundary surfaces, particularly preferably many inner boundary surfaces. Without the inner boundary surfaces, the material of the second electrode layer would thus be preferably completely transparent. In particular, the diffuse reflectivity described herein can be achieved, e.g., by a non-absorbing, or only slightly absorbing, polycrystalline material in which the diffuse reflection is achieved by a multiple partial reflection at the crystal boundaries. As an alternative thereto, the second electrode layer can also comprise a particle composite or a particle assembly. In this respect, the second electrode layer can be formed, e.g., as a dispersion, i.e., in principle for instance as a white color, in which one or more of the previously mentioned materials are present as a particle assembly. In this case, the second electrode layer can thus comprise non-absorbing particles in a non-absorbing matrix, wherein the particles and the matrix have a refractive index difference as large as possible so that an effective scattering of light can be produced at the boundary surfaces of the particles with the matrix. The refractive index of the matrix can be adapted, in particular in the sense described hereinafter, to the refractive index of the organic functional layer stack or even be higher than the index for the light from the organic functional layer stack to be able to effectively penetrate into the second electrode layer. The matrix can, for example, comprise or consist of a highly refractive polymer. In contrast to typical translucent scattering layers, though which light is radiated, the second electrode layer has such a large thickness and/or particle concentration that the second electrode layer is not translucent but rather completely reflective.

It may also be particularly advantageous if the second electrode layer, formed as a reflective diffuser layer, of the second electrode has a refractive index adapted to a refractive index of the organic functional layer stack. This means, in other words, that the second electrode layer can have a refractive index in the region of the semiconductive organic materials used in the organic functional layer stack. Furthermore, it may be advantageous if the refractive index of the second electrode layer of the second electrode is additionally or alternatively adapted to the refractive index of the translucent first electrode layer of the second electrode. By way of such a refractive index adaptation, it can be possible to ensure that light can penetrate into the second electrode layer as efficiently as possible. The fact that two refractive indexes are adapted to each other can mean in particular that they differ from each other by less than or equal to 20% or less than or equal to 10% or less than or equal to 5%. Furthermore, the refractive index of the second electrode layer can also be higher than the refractive index of the organic functional layer stack and/or of the first electrode layer. For example, barium sulfate typically has a refractive index of approximately 1.64 while magnesium oxide can have a refractive index of approximately 1.73 to 1.77. Polymer semiconductor materials typically have a refractive index in the region of 1.7, while organic functional materials based on small molecules typically have a refractive index in the region of 1.8. Therefore, barium sulfate, e.g., in conjunction with polymeric organic functional materials and magnesium oxide in conjunction with organic functional materials based on small molecules may be particularly suitable.

Furthermore, the second electrode layer can also comprise, e.g., titanium dioxide with a refractive index of typically greater than or equal to 2.5 and less than or equal to 2.9 depending upon the crystal type and crystal direction. Furthermore, zinc sulfide with a refractive index of typically 2.37, zinc oxide with a refractive index of typically 2 and antimony oxide with a refractive index of typically greater than or equal to 2.1 and less than or equal to 2.3 are also feasible.

The second electrode may be arranged on a side of the organic functional layer stack facing away from the substrate. For example, an encapsulation arrangement can be arranged directly on the second electrode formed as a so-called top electrode. In this case, the first electrode is accordingly arranged between the organic functional layer stack and the substrate so that light generated during operation is coupled out of the organic light-emitting component through the first electrode and accordingly also through the substrate. In this case, the substrate is likewise translucent. In this case, the organic light-emitting component is designed as a so-called bottom emitter.

The second electrode may be arranged between the organic functional layer stack and the substrate. The second electrode layer, formed as a so-called bottom electrode, can be arranged, for example, directly on the substrate. The substrate can thus initially be provided with the second electrode layer onto which the translucent electrically conductive first electrode layer is then applied. Then, the organic functional layer stack and the further layers of the organic light-emitting component are applied in the usual manner. In this case, the first electrode is arranged on the side of the organic functional layer stack facing away from the substrate and, therefore, the organic light-emitting component is formed as a so-called top emitter that emits light generated during operation from the side opposite the substrate.

The second electrode layer may be formed as a substrate for the first electrode layer, the organic functional layer stack and the first electrode. This means in other words that the second electrode layer forms the substrate for the organic light-emitting component and this is free of any further substrate, in particular a substrate as described further above.

The first and second electrodes may each be formed with a large surface. As an alternative thereto, the first electrode or the second electrode can be structured and can comprise at least two mutually separated electrode regions that, separately from each other, can be electrically contacted and actuated. For example, the first or second electrode can be structured such that the organic light-emitting component comprises a multiplicity of individually actuatable image points or regions and, therefore, the organic light-emitting component can be formed as an illumination source having a variable lighting surface or as a display apparatus, e.g., as a display or for displaying pictograms. The fact that the second electrode is structured can mean in particular that the first electrode layer is structured. The second electrode layer can likewise be structured or preferably be formed with a large surface and unstructured.

A still further encapsulation arrangement can be arranged above the electrodes and the organic layers. The encapsulation arrangement can be designed, e.g., in the form of a glass cover or in the form of a thin-film encapsulation.

A glass cover, e.g., in the form of a glass substrate that can comprise a cavity can be adhered to the substrate by an adhesive layer or a glass solder or can be fused with the substrate. A moisture-absorbing substance (getter), e.g., consisting of zeolite can furthermore be stuck into the cavity to bind moisture or oxygen penetrating through the adhesive. Furthermore, an adhesive containing a getter material can also be used to attach the cover to the substrate.

An encapsulation arrangement formed as a thin-film encapsulation is understood to mean a single-layered or multi-layered apparatus suitable to form a barrier with respect to atmospheric substances, in particular with respect to moisture and oxygen and/or with respect to further harmful substances such as, e.g., corrosive gases, e.g., hydrogen sulfide. In this respect, the encapsulation arrangement can comprise one or more layers each having a thickness of less than or equal to several 100 nm. In particular, the thin-film encapsulation can comprise or consist of thin layers that, e.g., are applied using an atomic layer deposition (ALD) process. Suitable materials for the layers of the encapsulation arrangement are, for example, aluminum oxide, zinc oxide, zirconium oxide, titanium oxide, hafnium oxide, lanthanum oxide, tantalum oxide. Preferably, the encapsulation arrangement comprises a layer sequence having a plurality of thin layers each having a thickness between one atom layer and 10 nm, the limit values being included. As an alternative to or in addition to thin layers produced using ALD, the encapsulation arrangement can comprise at least one or a plurality of further layers, i.e., in particular barrier layers and/or passivation layers deposited by thermal vapor deposition or by a plasma-assisted process, for instance sputtering or plasma-enhanced chemical vapor deposition (PECVD). Suitable materials therefore can be the previously mentioned materials as well as silicon nitride, silicon oxide, silicon oxynitride, indium tin oxide, indium zinc oxide, aluminum-doped zinc oxide, aluminum oxide and mixtures and alloys of the materials. The one or more further layers can each have, e.g., a thickness 1 nm to 5 μm and preferably 1 nm to 400 nm, the limit values being included.

Thin-film encapsulations are described, for example, in WO 2009/095006 A1 and WO 2010/108894 A1, their respective contents being incorporated herein by reference in its entirety.

Further advantages and developments are apparent from the examples described below in conjunction with the figures.

In the examples and figures, like or similar elements or elements acting in an identical manner may each be provided with the same reference numerals. The illustrated elements and their size ratios with respect to each other are not to be considered as being to scale. Rather, individual elements such as, e.g., layers, components, devices and regions, can be illustrated excessively large for improved clarity and/or for improved understanding.

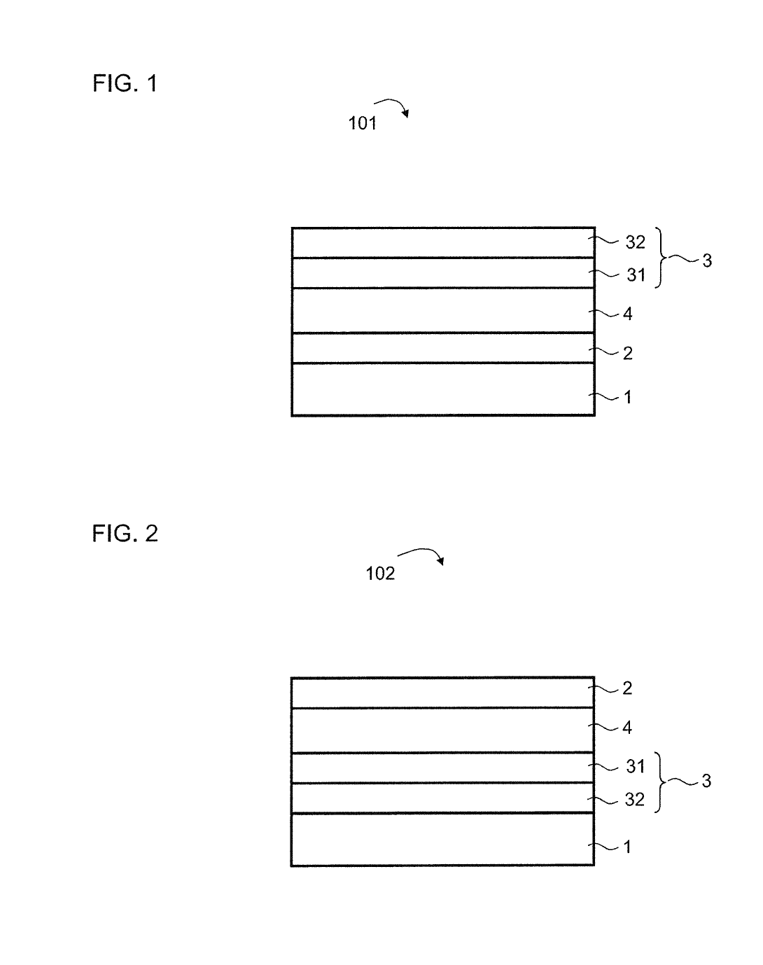

FIG. 1 illustrates an example of an organic light-emitting component 101 formed as a so-called bottom emitter. The organic light-emitting component 101, designed as an organic light-emitting diode (OLED), comprises in this respect a substrate 1 on which a translucent first electrode 2 and a second electrode 3 are arranged. Arranged between the electrodes 2, 3 is an organic functional layer stack 4 having at least one or more organic light-emitting layers configured to generate light during operation of the organic light-emitting component 101 by way of electroluminescence.

The substrate 1 and the first electrode 2 are translucent, and therefore light generated in the organic functional layer stack during operation of the organic light-emitting component 101 can be emitted outwardly therethrough. To achieve an outcoupling efficiency as high as possible, in such known bottom emitter devices, typically an internal outcoupling layer in the form of a translucent scattering layer is arranged between the substrate and the lower first electrode. In contrast to those typical structures, the organic light-emitting component 101 is free of such an additional translucent scattering layer on the side of the organic functional layer stack 4 opposite the second electrode 3.

In the illustrated example, the substrate 1 can comprise in particular glass and/or synthetic material and, e.g., be formed as a film or plate consisting of or having glass and/or synthetic material or a glass-synthetic material laminate.

The translucent first electrode 2 can comprise in particular a transparent conductive oxide (TCO) such as, for example, indium tin oxide (ITO) applied on the substrate 1. Additionally or alternatively, other translucent electrically conductive materials mentioned above in the general part are also possible.

The organic functional layer stack 4 can comprise in addition to one or more organic light-emitting layers, charge carrier transport layers and/or charge carrier blocking layers such as, e.g., hole transport layers, electrode transport layers, hole blocking layers, electrode blocking layers and further organic functional layers.

The second electrode 3 is diffusely reflective. This means in particular that the second electrode 3 is diffusely scattering and is as highly reflective as possible, i.e., has a diffuse reflection with as high a reflection coefficient as possible. As a result, compared to a specular reflection, the light generated in the organic functional layer stack 4 during operation of the organic light-emitting component 101 is reflected not in a targeted manner but in an untargeted manner as possible, in particular, if possible, with a Lambertian radiation characteristic and, therefore, the light irradiated by the organic functional layer stack 4 onto the second electrode 3 is distributed uniformly in all spatial directions, if possible. Waveguide effects in the layers of the organic light-emitting component 101 can hereby be reduced or even completely prevented.

The second electrode 3 already used as internal outcoupling structure in its function as a reflective diffuser layer, comprises in particular two electrode layers 31, 32. The first electrode layer 31 is translucent and electrically conductive and permits the electrical functionality of the second electrode 3. The first electrode layer 31 can comprise in this respect in particular a transparent conductive oxide, a translucent metal or silver nanowires or a combination thereof. This can mean in particular that the first electrode layer 31 comprises at least one layer consisting of a transparent conductive oxide, a translucent metal layer or a layer with silver nanowires. Furthermore, it is also possible that the first electrode layer 31 comprises a combination of the materials or layers such as, for example, at least one layer consisting of a transparent conductive oxide and at least one translucent metal layer.

To achieve an efficiency of the organic light-emitting component 101 as high as possible, it is advantageous if the first electrode layer 31 has an absorption as low as possible and thus a permeability as high as possible for light generated in the organic functional layer stack 4 during operation. Depending upon the material, the first electrode layer 31 can be produced, e.g., by sputtering, for instance in a TCO such as ITO, by thermal evaporation, for instance in a translucent metal layer, or by a solvent-based process, e.g., in silver nanowires. Furthermore, it may also be possible that the first electrode layer 31 of the second electrode 3 and the first electrode 2 are formed identically, i.e., comprise an identical material or an identical material/layer combination. As an alternative thereto, the first electrode 2 and the first electrode layer 31 can also comprise different materials.

The second electrode 3 comprises, as the second electrode layer 32, a diffusely scattering layer as highly reflective as possible. In this respect, the diffusely reflective second electrode layer 32 comprises in particular a material permitting a diffuse reflection and a high reflection coefficient. Magnesium oxide (MgO) and/or barium sulfate (BaSO₄) can be used, for example, as materials for the second electrode layer 32 of the second electrode 3. Layers consisting of these materials have very high reflection coefficients, for instance in magnesium oxide of greater than or equal to 95% and in barium sulfate of greater than or equal to 98%, in combination with very good diffuser properties with almost Lambertian radiation of the reflected light. In particular, it is advantageous if the high reflectivity of the second electrode layer 32 is not based on a boundary surface scattering at the surface of the second electrode layer 32, but is based on a volume scattering within same, i.e., a scattering at particle and/or crystal boundary surfaces within the second electrode layer 32 formed as a diffuser layer. In this respect, the second electrode layer 32 is preferably produced in the form of a layer having as many particle and/or crystal boundary surfaces as possible. For example, magnesium oxide can be applied by sputtering or thermal evaporation and barium sulfate can be applied by spray coating.

To ensure that the light generated in the organic functional layer stack 4 can penetrate as effectively as possible into the second electrode layer 32 formed as a diffuser layer, it is advantageous if the refractive index of the second electrode layer 32 is in the region of the refractive indexes of the used organic semiconductor materials of the organic functional layer stack 4 and/or in the region of the translucent first electrode layer 31. The refractive indexes of the second electrode layer 32 and of the organic functional layer stack 4 and/or of the first electrode layer 31 can be adapted to each other for this purpose and, for example, can differ from each other by less than or equal to 20% or less than or equal to 10% or less than or equal to 5%. In barium sulfate as the material for the second electrode layer 32 having a typical refractive index of approximately 1.64, this can be the case, for example, in combination with polymeric semiconductor materials for the organic functional layer stack 4 having a typical refractive index of approximately 1.7, while magnesium oxide having a typical refractive index of 1.73 to 1.77 is also suitable for the use of organic small molecules having a refractive index of typically 1.8 for the organic functional layer stack 4.

The organic light-emitting component 101 illustrated in FIG. 1 can be formed like a typical OLED with the advantages of a substrate, without an internal outcoupling layer having to be arranged between the substrate 1 and the first electrode 2 or even between the first electrode 2 and the organic functional layer stack 4. The risk of defects is hereby obviated and also no planarization layers are required as are used, for example, in the prior art to planarize internal outcoupling layers. As a result, for example, a glass coated using ITO can be provided as a substrate 1 with a translucent electrode 2 and the typical process steps such as, e.g., photolithography steps can be used without the risk of damaging an internal outcoupling layer located on the substrate. Even without an internal outcoupling layer arranged in the region of the substrate 1, in the illustrated organic light-emitting component 101 a high efficiency can be achieved by a high outcoupling of light, in that the second electrode 3 acting as an outcoupling structure and formed as a top-electrode is formed on the organic functional layer stack 4 to be diffusely scattering and highly reflective.

The organic light-emitting component 101 can comprise further layers, e.g., an encapsulation arrangement above the electrodes 2, 3 and the organic functional layer stack 4, not illustrated here for reasons of clarity. In particular, an encapsulation arrangement can be arranged directly on the second electrode layer 32 of the second electrode 3.

FIG. 2 illustrates a further example of an organic light-emitting component 102 which is a modification of the preceding example and is formed as a so-called top emitter instead of the bottom emitter illustrated in FIG. 1. In this respect, the organic light-emitting component 102 comprises the second electrode 3 between the substrate 1 and the organic functional layer stack 4, the second electrode being formed as a so-called bottom electrode. The translucent first electrode 2 is arranged on the organic functional layer stack 4, as seen from the substrate, and therefore the light generated in the organic functional layer stack 4 during operation of the organic light-emitting component 102 can be emitted upwardly therethrough, as seen from the substrate 1.

The second electrode 3 can be arranged in particular directly on the substrate 1. In other words, the substrate 1 is initially provided with the second electrode layer 32 formed as a diffuser layer and applied directly onto the substrate 1. The translucent electrically conductive first electrode layer 31 is applied thereon. Then, with respect to the further layers, i.e., the organic functional layer stack 4, the translucent first electrode 2 and, e.g., also an encapsulation arrangement, the organic light-emitting component 102 is formed in a typical manner as is known.

The electrode layers 2, 3 and the organic functional layer stack 4 can comprise materials as described in conjunction with the organic light-emitting component 101 of FIG. 1.

As an alternative to the examples illustrated in FIGS. 1 and 2, it is also possible that the second electrode layer 32 is formed as a substrate for the first electrode layer 31, the organic functional layer stack 4 and the first electrode 2 and, therefore, the resulting organic light-emitting component is free of a further substrate, in particular a substrate 1 as previously described.

The examples illustrated in the figures can comprise, alternatively or in addition, further features described above in the general part.

The description made with reference to the examples does not restrict this disclosure to these examples. Rather, the disclosure encompasses any new feature and any combination of features, including in particular any combination of features in the appended claims, even if the feature or combination is not itself explicitly indicated in the claims or examples.

This application claims priority of DE 10 2014 106 549.2, the subject matter of which is hereby incorporated by reference.

1-13. (canceled)

14. An organic light-emitting component comprising:
a translucent first electrode and a second electrode; and
an organic functional layer stack having at least one organic light-emitting layer between the first and second electrodes,
wherein the second electrode is diffusely reflective.

15. The component according to claim 14, wherein the second electrode comprises a translucent electrically conductive first electrode layer and, on a side of the first electrode layer facing away from the organic functional layer stack, a diffusely reflective second electrode layer.

16. The component according to claim 14, wherein the electrodes and the organic functional layer stack are arranged on a substrate and the second electrode is arranged on a side of the organic functional layer stack facing away from the substrate.

17. The component according to claim 14, wherein the electrodes and the organic functional layer stack are arranged on a substrate and the second electrode is arranged between the organic functional layer stack and the substrate.

18. The component according to claim 17, wherein the second electrode layer is arranged directly on the substrate.

19. The component according to claim 15, wherein the second electrode layer is formed as a substrate for the first electrode layer, the organic functional layer stack and the first electrode.

20. The component according to claim 14, wherein the second electrode layer comprises a multiplicity of particles and/or crystals with boundary surfaces for diffuse reflection.

21. The component according to claim 14, wherein the second electrode layer is diffusely scattering with a Lambertian radiation characteristic.

22. The component according to claim 14, wherein the second electrode layer has a reflection coefficient of greater than or equal to 95%.

23. The component according to claim 14, wherein the second electrode layer comprises at least one material selected from the group consisting of magnesium oxide and barium sulfate.

24. The component according to claim 14, wherein the second electrode layer has a refractive index adapted to a refractive index of the organic functional layer stack.

25. The component according to claim 14, wherein the first electrode layer comprises at least one layer selected from the group consisting of a layer with a transparent conductive oxide, a translucent metal layer and a layer with silver nanowires.

26. The component according to claim 14, wherein the organic light-emitting component is free of a translucent scattering layer on a side of the organic functional layer stack facing away from the second electrode.

27. The component according to claim 14, wherein the second electrode comprises a translucent electrically conductive first electrode layer and, on a side of the first electrode layer facing away from the organic functional layer stack, a diffusely reflective second electrode layer, and the second electrode layer is formed as a substrate for the first electrode layer, the organic functional layer stack and the first electrode.

28. An organic light-emitting component comprising:
a translucent first electrode and a second electrode; and
an organic functional layer stack having at least one organic light-emitting layer between the first and second electrodes,
wherein the second electrode is diffusely reflective, and
the second electrode layer comprises a multiplicity of crystals with boundary surfaces for diffuse reflection.

29. An organic light-emitting component comprising:
a translucent first electrode and a second electrode; and
an organic functional layer stack having at least one organic light-emitting layer between the first and second electrodes,
wherein the second electrode is diffusely reflective, and
the second electrode layer comprises barium sulfate.
